(19) United States
(12) Patent Application Publication
(10) Pub. No.: US 2025/0358941 A1
(43) Pub. Date: Nov. 20, 2025

(54) SECURITY GRILL PANEL FOR A CABINET AND A METHOD OF INSTALLING

(71) Applicant: Vertiv Corporation, Westerville, OH (US)

(72) Inventors: Michael D. Blom, JR., Opelika, AL (US); Matthew A. Podemski, Auburn, AL (US); Rahul Musale, Westerville, OH (US); Mangesh Kute, Westerville, OH (US)

(21) Appl. No.: 19/082,947

(22) Filed: Mar. 18, 2025

(30) Foreign Application Priority Data
May 18, 2024 (IN) 202421039132

(51) Int. Cl. H05K 5/02; H01M 50/204; H01M 50/251; H01M 50/262

(52) U.S. Cl. CPC H05K 5/0208; H01M 50/204; H01M 50/251; H01M 50/262; H01M 2220/10

(57) ABSTRACT

A grill panel and method are disclosed for preventing tampering and theft of components (e.g., batteries) in a cabinet. The grill panel may be configured to be mounted on an operative front portion of a cabinet. The grill panel may include a bottom grill panel configured to be mounted on a lower portion of the cabinet. The grill panel may include a top grill panel configured to interlock with the bottom grill panel and configured to be mounted over the bottom grill panel. An operative portion of the top grill panel may be configured to interlock with an operative portion of the bottom grill panel.

### CROSS-REFERENCE TO RELATED APPLICATION

The present application claims the benefit of India Provisional Patent Application 202421039132, filed May 18, 2024, titled A SECURITY GRILL PANEL FOR A CABINET AND A METHOD OF INSTALLING THERE OF, which is incorporated herein by reference in the entirety.

### TECHNICAL FIELD

The present disclosure relates to anti-theft devices, and, in particular, to a security grill panel for a cabinet.

### BACKGROUND

The background information herein below relates to the present disclosure but is not necessarily prior art. Batteries serve as a power source across various industrial sectors. Typically, these batteries are housed within battery storage cabinets, also known as battery storage compartments, or power distribution racks. These cabinets are designed to accommodate not only the batteries but also various other electronic components essential for their efficient operation. However, a prevalent issue with conventional storage cabinets lies in the security measures employed, primarily revolving around the use of conventional locks.

Unfortunately, these conventional locks are susceptible to tampering, posing a significant challenge in safeguarding the batteries and associated electronic devices within the cabinet in remote areas. The possibility threat of theft presents a substantial risk, potentially resulting in significant losses for the industry. Additionally, the presence of numerous conventional locks often contributes to the cabinet's weight, rendering it cumbersome and challenging to handle.

Therefore, there is a need for a security grill panel for a cabinet and a method of installing thereof that can address the aforementioned drawbacks.

### SUMMARY

A grill panel is disclosed in accordance with one or more illustrative embodiments of the present disclosure. In one illustrative embodiment, the grill panel may be configured to be mounted on an operative front portion of a cabinet. In another illustrative embodiment, the grill panel may include a bottom grill panel configured to be mounted on a lower portion of the cabinet. In another illustrative embodiment, the grill panel may include a top grill panel configured to interlock with the bottom grill panel and configured to be mounted over the bottom grill panel. In another illustrative embodiment, an operative portion of the top grill panel may be configured to interlock with an operative portion of the bottom grill panel.

In a further aspect, the grill panel may include at least a pair of top brackets, each top bracket including a flange. In another illustrative embodiment, the top grill panel may include at least a pair of flanges, where each flange of the top grill panel may be configured to abut a corresponding flange of the at least the pair of the top brackets when the top grill panel is mounted over the bottom grill panel. In another illustrative embodiment, the corresponding flange of the top bracket may include a hole, and the flange of the top grill panel may include a cavity. The hole of the corresponding flange of the top bracket may align with the cavity of the top grill panel when the flange of the top grill panel abuts the corresponding flange of the top bracket.

In another illustrative embodiment, the corresponding flange of each top bracket and the flange of the top grill panel may be configured to receive a puck lock configured to enclose and lock the corresponding flange of the top bracket and the flange of the top grill panel together. In another illustrative embodiment, the puck lock may include a smart puck lock configured to be connected to a cloud server and remotely actuated.

In another illustrative embodiment, the grill panel may include an adapter plate configured to be mounted to an inner operative bottom surface of the cabinet. The adapter plate may be configured to form a predefined gap between an operative edge of the adapter plate and the operative portion of the cabinet. A lower operative portion of the bottom grill panel may be configured to be received within the predefined gap.

In another illustrative embodiment, the grill panel may include a center bracket configured to be mounted to the operative front portion of the cabinet. In another illustrative embodiment, the center bracket may be configured to partition the cabinet into an upper half cabinet and a lower half cabinet. An upper operative portion of the bottom grill panel may be configured to be received and fastened to the center bracket.

In another illustrative embodiment, the grill panel may include at least two side plates and at least one base plate configured to be mounted in an inner operative portion of an upper half of the cabinet. The at least two side plates and the at least one base plate may be configured as a protective barrier for components from external tampering.

In another illustrative embodiment, the bottom grill panel and the top grill panel may be defined by a cage structure and may include a webbed portion including an interconnected pattern of elements.

A cabinet is disclosed in accordance with one or more illustrative embodiments of the present disclosure. In one illustrative embodiment, the cabinet includes a grill panel mounted on an operative front portion of the cabinet. In another illustrative embodiment, the cabinet includes a door panel configured to enclose the grill panel. In another illustrative embodiment, the cabinet includes a plurality of racks, each rack equipped with a battery restraining bracket. In another illustrative embodiment, the grill panel includes a bottom grill panel configured to be mounted on a lower portion of the cabinet. In another illustrative embodiment, the grill panel includes a top grill panel configured to interlock with the bottom grill panel and configured to be mounted over the bottom grill panel. In another illustrative embodiment, an operative portion of the top grill panel is configured to interlock with an operative portion of the bottom grill panel.

In another illustrative embodiment, the grill panel may include at least a pair of top brackets, each top bracket including a flange. In another illustrative embodiment, the top grill panel may include at least a pair of flanges, where each flange of the top grill panel is configured to abut a corresponding flange of the at least the pair of the top brackets when the top grill panel is mounted over the bottom grill panel. In another illustrative embodiment, the top brackets may be mounted in proximity to a side edge of the cabinet. In another illustrative embodiment, the top brackets may be concealed when the top grill panel is mounted.

In another illustrative embodiment, the interlocking of the operative portion of the top grill panel with the operative portion of the bottom grill panel may form an interlocking zone that restricts unauthorized opening or tampering with the top grill panel and the bottom grill panel. In another illustrative embodiment, the grill panel may include an adapter plate mounted to an inner operative bottom surface of the cabinet. In another illustrative embodiment, the adapter plate may form a predefined gap between an operative edge of the adapter plate and an operative portion of the cabinet. In another illustrative embodiment, a lower operative portion of the bottom grill panel may be received within the predefined gap.

In another illustrative embodiment, the grill panel may include a center bracket mounted to the operative front portion of the cabinet. In another illustrative embodiment, the center bracket may partition the cabinet into an upper half cabinet and a lower half cabinet. In another illustrative embodiment, an upper operative portion of the bottom grill panel may be received and fastened to the center bracket inside the cabinet by fasteners.

In another illustrative embodiment, the grill panel may include at least two side plates and at least one base plate mounted in an inner operative portion of an upper half of the cabinet. In another illustrative embodiment, the side plates and the base plate may provide a protective barrier. In another illustrative embodiment, the corresponding flange of the top bracket may include a hole, and the flange of the top grill panel may include a cavity. In another illustrative embodiment, the hole of the corresponding flange of the top bracket may align with the cavity of the top grill panel when the flange of the top grill panel abuts the corresponding flange of the top bracket.

A method of mounting a grill panel on an operative portion of a cabinet is disclosed in accordance with one or more illustrative embodiments of the present disclosure. In one illustrative embodiment, the method includes providing a bottom grill panel for mounting onto a lower portion of the cabinet and assembling the bottom grill panel onto the lower portion of the cabinet. In another illustrative embodiment, the method includes fastening a top portion of the bottom grill panel to a center bracket of the cabinet. In another illustrative embodiment, the method includes providing a pair of top brackets and mounting the pair of the top brackets onto an operative edge defined along a vertical column of the cabinet. In another illustrative embodiment, the method includes providing a top grill panel and mounting the top grill panel. In another illustrative embodiment, the method includes fastening a side portion of the top grill panel onto operative sides of the top brackets using fasteners. In another illustrative embodiment, the method includes locking flanges of the top grill panel to flanges of the top bracket using a puck lock. In another illustrative embodiment, the method includes closing a door panel.

Some of the objects of the present disclosure, which at least one embodiment herein satisfies, are as follows:

It is an object of the present disclosure to ameliorate one or more problems of the prior art or to at least provide a useful alternative.

An object of the present disclosure is to provide a security grill panel for a cabinet with advanced locking mechanisms that can be resistant to tampering.

Another object of the present disclosure is to provide a security grill panel for a cabinet that can restrict the access for the item stored therein and thus maintaining the robust security measures.

Yet another object of the present disclosure is to provide a security grill panel for a cabinet that can offer innovative structural configurations to minimize the overall weight of the cabinet.

Still another object of the present disclosure is to provide a security grill panel for a cabinet that can integrate modern locking technologies such as biometric authentication, RFID (Radio-Frequency Identification), or IoT (Internet of Things) connectivity to enhance security features and provide remote monitoring capabilities.

Yet another object of the present disclosure is to provide a security grill panel for a cabinet that can be tailored according to specific industry requirements.

Still another object of the present disclosure is to provide a method of installing the grill panel on the cabinet.

Yet another object of the present disclosure is to provide a security grill panel for a cabinet that can be installed at the site to the Cabinet without any additional modification in the cabinet configuration.

Other objects and advantages of the present disclosure will be more apparent from the following description when read in conjunction with the accompanying figures, which are not intended to limit the scope of the present disclosure.

It is to be understood that both the foregoing general description and the following detailed description are exemplary and explanatory only and are not necessarily restrictive of the invention as claimed. Also, it is to be understood that the phraseology and terminology used herein is for the purpose of description and should not be regarded as limiting. The accompanying drawings, which are incorporated in and constitute a part of the specification, illustrate embodiments of the invention, and, together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1 illustrates an isometric view of the cabinet with a grill panel and a door panel, in accordance with one or more embodiments of the present disclosure.

FIG. 2 illustrates an exploded isometric view of the cabinet, in accordance with one or more embodiments of the present disclosure.

FIG. 3 illustrates isometric views of the grill panel, in accordance with one or more embodiments of the present disclosure.

FIG. 4 illustrates an isometric view of mounting of a bottom grill panel on the cabinet, in accordance with one or more embodiments of the present disclosure.

FIG. 5 illustrates an isometric view of mounting of a top bracket on an operative portion of the cabinet, in accordance with one or more embodiments of the present disclosure.

FIG. 6A illustrates an isometric view of interlocking of a top grill panel with an operative portion of the bottom grill panel, in accordance with one or more embodiments of the present disclosure.

FIG. 6B illustrates an isometric view of abutment of the top grill panel on the top bracket along with the side plates and base plate, in accordance with one or more embodiments of the present disclosure.

FIG. 7A illustrates an enlarge view of a puck lock mounting zone, in accordance with one or more embodiments of the present disclosure.

FIG. 7B illustrates installation of a puck lock in the puck lock mounting zone, in accordance with one or more embodiments of the present disclosure.

FIG. 8 illustrates a process flow diagram depicting a method mounting the grill panel on the operative portion of the cabinet, in accordance with one or more embodiments of the present disclosure.

### LIST OF REFERENCE NUMERALS

100 Cabinet
10 Grill panel
12 Top grill panel
12a Flange of top grill panel
14 Bottom grill panel
16 Door panel
18 Puck lock
20 Top bracket
20a Flange of top bracket
22 Centre bracket
24 Fastener
26 Adapter plate
28 Battery restraining bracket
30 Battery tray or rack
32 Interlocking zone
34a Side plate
34b Base plate

### DETAILED DESCRIPTION

Reference will now be made in detail to the subject matter disclosed, which is illustrated in the accompanying drawings.

Embodiments, of the present disclosure, will now be described with reference to the accompanying drawings.

Typically, batteries are housed within storage battery cabinets, also known as storage battery compartments. These cabinets are designed to accommodate not only the batteries but also various other electronic components essential for their efficient operation. However, a prevalent issue with conventional storage cabinets lies in the security measures employed, primarily revolving around the use of conventional locks.

Unfortunately, these conventional locks are susceptible to tampering, posing a significant challenge in safeguarding the batteries and associated electronic devices within the cabinet in remote areas. The possibility threat of theft presents a substantial risk, potentially resulting in significant losses for the industry. Additionally, the presence of numerous conventional locks often contributes to the cabinet's weight, rendering it cumbersome and challenging to handle.

To overcome the aforementioned drawbacks, the present disclosure contemplates a grill panel for a cabinet.

The grill panel and method of installing the grill panel of the present disclosure described herein has several technical advantages including that the grill panel: 1) may be resistant to tampering, ensuring the secure storage of batteries and electronic devices; 2) may facilitate easy access to stored items while maintaining robust security measures; 3) may offer innovative structural configurations to minimize the overall weight of the cabinet, enhancing portability and ease of handling without compromising on durability or security; 4) may integrate modern locking technologies such as biometric authentication, RFID (Radio-Frequency Identification), or IoT (Internet of Things) connectivity to enhance security features and provide remote monitoring capabilities; 5) may be installed at the site; and 6) may be tailored according to specific industry requirements, ensuring versatility and compatibility with diverse storage needs.

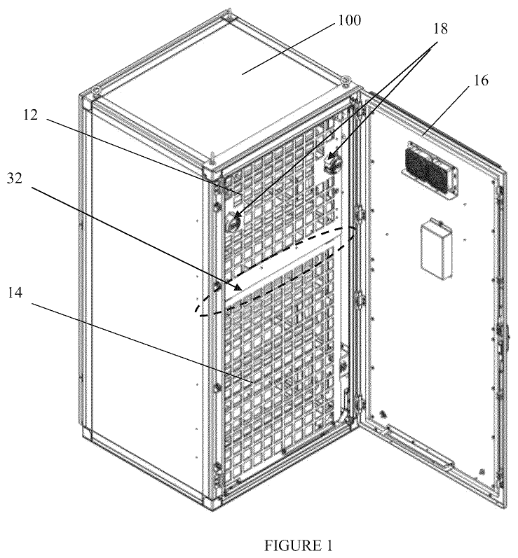

FIGS. 1 through 7 illustrate a cabinet 100 and system for preventing access to the internal components of the cabinet 100, in accordance with one or more embodiments of the present disclosure. The cabinet 100 may be characterized by having a cuboidal hollow structure.

FIG. 1 illustrates an isometric view of the cabinet 100 coupled to a grill panel 10 and including a door panel 16, in accordance with one or more embodiments of the present disclosure.

The cabinet 100 may be configured to securely house batteries and other electronic components (not shown), thus featuring multiple racks 30, each rack equipped with a battery restraining bracket 28. The restraining bracket 28 may be configured to be mounted (e.g., fastened using fasteners) on an operative outer periphery of the battery racks or tray 30. Prior to closing or locking the door panel 16, the grill panel 10 may be lockingly mounted onto an operative front portion of the cabinet 100.

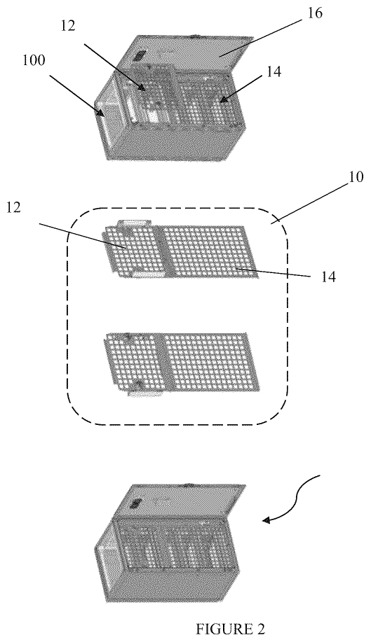

FIG. 2 illustrates an exploded isometric view of the cabinet 100, in accordance with one or more embodiments of the present disclosure.

In an embodiment, the racks 30 may be fastened with screws within the cabinet 100.

Further, the grill panel 10 may be split in to a bottom grill panel 14 (e.g., first grill panel 12) and a top grill panel 12 (e.g., second grill panel 14). These grill panels 12, 14 may be configured to be mounted on an operative front portion of the cabinet 100. The grill panels 12, 14 may be defined by a cage structure. The lower portion and the upper portion of the bottom grill panel 14 (and/or top grill panel 12) may include a webbed portion. For example, the webbed portion may include an interconnected pattern of elements, such as crisscrossed horizontal and vertical elements. For instance, the interconnected pattern of elements may include a grid pattern, a checkerboard pattern, an array of holes, and/or the like.

At least one center bracket 22 may be mounted to an operative front portion of the cabinet 100. In this way, the center bracket 22 partitions the cabinet in an upper half cabinet and a lower half cabinet to thereby facilitate ease of mounting the grill panel 10 to the cabinet 100. The bottom grill panel 14 may be configured to be secured to the lower half of the cabinet 100.

The split configuration of the grill panel 10 may be relatively convenient to handle compared to an unsplit configuration.

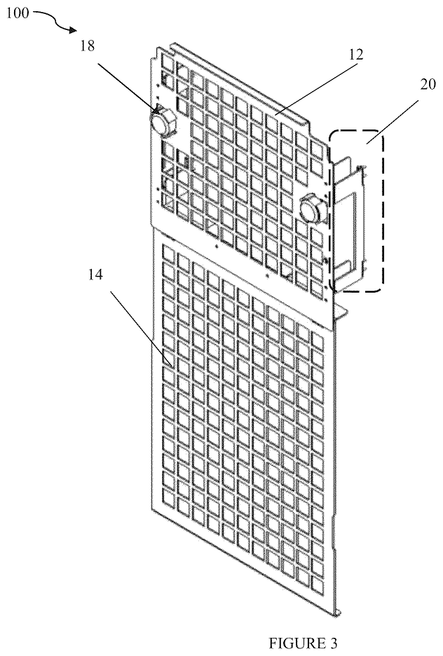

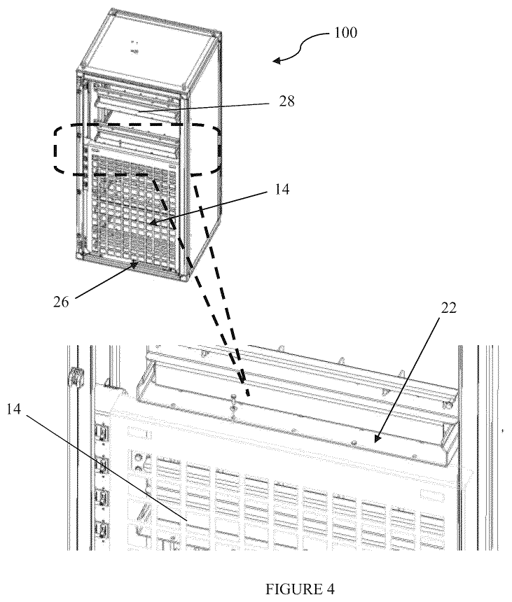

FIG. 3 illustrates an isometric view of the grill panel 10 and FIG. 4 illustrates an isometric view of mounting of a bottom grill panel 14 on the cabinet 100, in accordance with one or more embodiments of the present disclosure.

In an embodiment, an inner operative bottom surface of the cabinet 100 may be configured with an adapter plate 26, as shown in FIG. 4. The adapter plate 26 may be configured to be mounted in such a way that a predefined gap (e.g., slot) is formed between an operative edge of the adapter plate 26 and an operative portion of the cabinet 100.

In an operative configuration, a lower operative portion (e.g., lower edge, flange, or the like) of the bottom grill panel 14 may be received within the predefined gap and secured therein. In other words, the adapter plate 26 may define a slot for receiving the bottom grill panel 14. In addition, an upper operative portion (e.g., upper edge, flange, or the like) of the bottom grill panel 14 may be configured to be received and fastened to the center bracket 22 inside the cabinet 100 by virtue of fasteners 24.

Further, the upper half of the cabinet 100 may be equipped with at least a pair of top brackets 20, each featuring a flange and a hole (not shown) therein. The top bracket 20 may be configured to be mounted in proximity to an operative edge, which is defined along the vertical column of the cabinet 100.

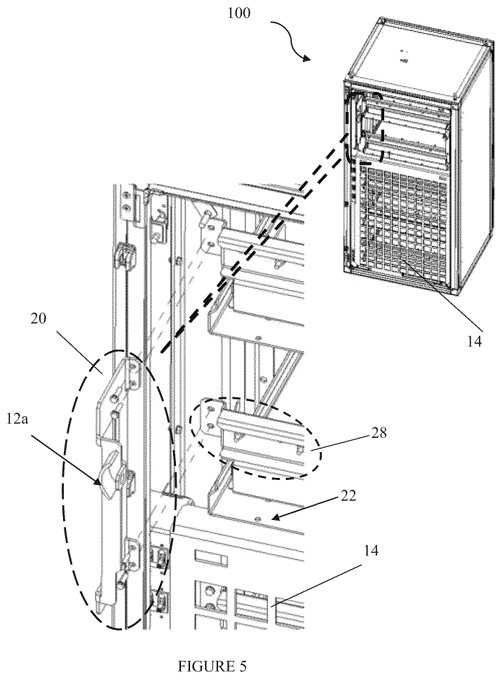

FIG. 5 illustrates an isometric view of mounting of a bracket 20 on the operative portion of the cabinet 100, in accordance with one or more embodiments of the present disclosure.

In an embodiment, each of the top brackets 20 may be mounted in proximity to a side edge (e.g., vertical support column) of the cabinet 100 by virtue of one or more fasteners. Since the top brackets 20 are mounted in proximity to the side edge of the cabinet 100, the top bracket 20 is concealed when the top grill panel 12 is mounted.

In an embodiment, a lower operative portion of the top grill panel 12 slides onto a slot (not shown) defined by an operative top portion of the bottom grill panel 14 while mounting the top grill panel 12 over the bottom grill panel 14. In this way, the lower operative portion of the top grill panel 12 interlocks with the operative top portion of the bottom grill panel 14 and forms (or defines) an interlocking zone 32. The interlocking of the operative portion of the top grill panel 12 with the operative portion of the bottom grill panel 14 fixedly joins the panels 12, 14 together and therefore restricts unauthorized opening or tampering with the grill panels 12, 14.

In an embodiment, the top grill panel 12 may be configured with at least a pair of flanges 12a. Each flange 12a may include a cavity (not shown) therein. The flange 12a provided on the top grill panel 12 may be configured such that during a lock-configuration of the top grill panel 14, the flange 12a of the top grill panel 12 and the flange 20a of the top brackets 20 abut (e.g., align) side by side. In this way, a hole defined on the flange 20a of the top bracket 20 may align with a central cavity defined on the flange 12a of the top grill panel 12. This abutment facilitates locking of the top grill panel 12 to the top bracket 20 using at least one puck lock 18.

The puck lock 18 may be configured to enclose the flanges 12a, 20a and lock the flanges 12a, 20a together when in a mounted location on the grill panel 10. The puck lock 18 may lock the hole of the top bracket 20 with the cavity of the top grill panel 14 in an operative configuration.

Advantageously, the battery restraining bracket 28 restricts unauthorized access to the components such as batteries or other electronic components stored in the rack 30 from outside the grill panel 10.

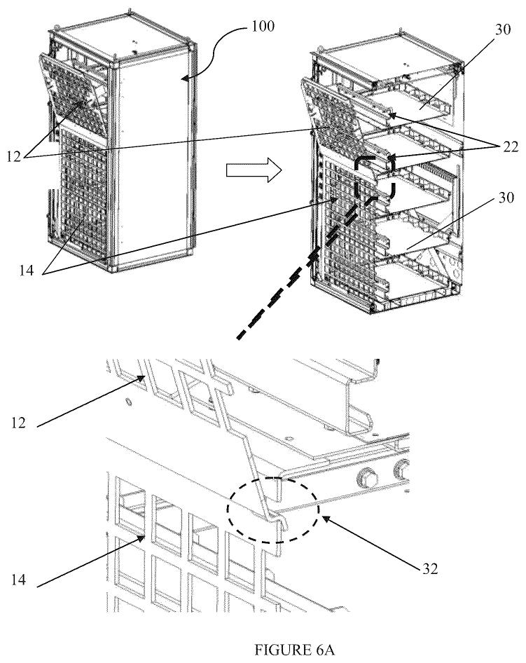

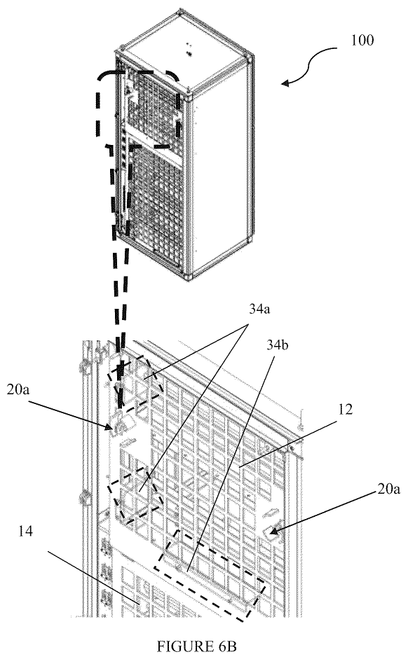

FIG. 6A illustrates an isometric view of mounting of a top grill panel 12 on the cabinet 100, and FIG. 6B illustrates an isometric view of abutment of the top grill panel 12 on the top bracket 20, in accordance with one or more embodiments of the present disclosure.

In one embodiment, an inner operative portion of the upper half of the cabinet 100 includes at least two side plates 34a and at least one base plate 34b. These plates 34a, 34b serve as a protective barrier, safeguarding the battery pack and other electronic components from external tampering when the top grill panel 12 is affixed to the upper half of the cabinet 100. The configuration and positioning of these side plates 34a and the base plates 34b are illustrated in FIG. 6B.

In at least one embodiment, only the top grill panel 14 is secured with the puck locks 18 and only the bottom grill panel 12 is interlocked with the top grill panel 14. The bottom grill panel 12 does not need to necessarily be locked with separate puck locks if the bottom grill panel 12 is already interlocked with the top grill panel 14. Hence, advantageously, the split and interlocked configuration of the grill panels 12, 14 reduces the amount of locking required and reduces the overall handling weight.

In an embodiment, the top grill panel 12 may be configured to be mounted to an operative portion of the top brackets 20 by virtue of the fasteners 24. The operative side portion of the top grill panel 12 may rest on an operative portion of the top brackets 20 and be screwed thereto by fasteners 24.

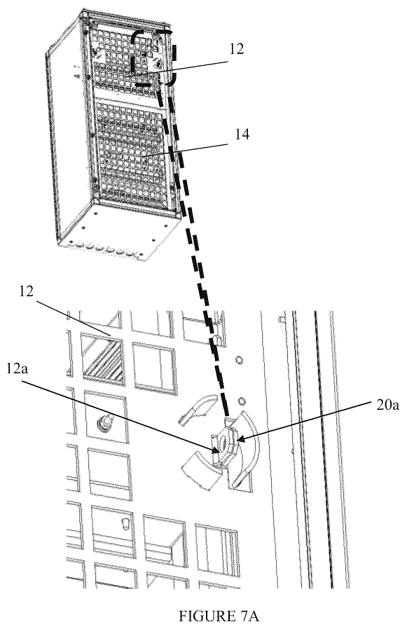

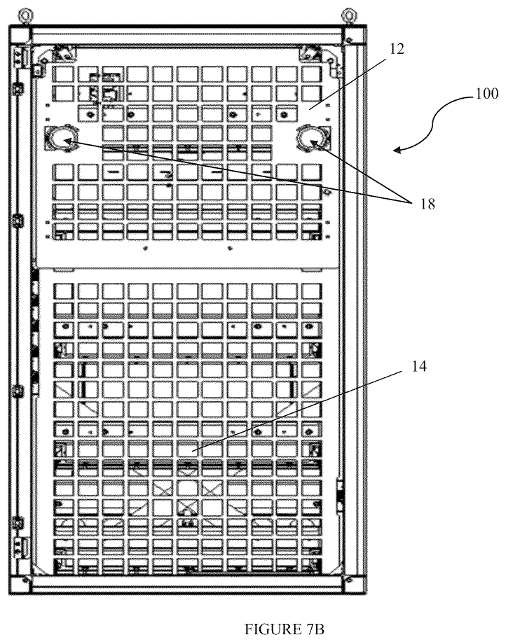

FIG. 7A illustrates an enlarged view of a puck lock mounting zone, and FIG. 7B illustrates an installation of a puck lock 18 in the puck lock mounting zone, in accordance with one or more embodiments of the present disclosure.

Advantageously, the puck lock 18 provided on the cabinet 100 may include a smart puck lock configured to be connected to a cloud server. Therefore, a registered user may remotely actuate the puck lock 18 using a mobile device connected to the cloud server.

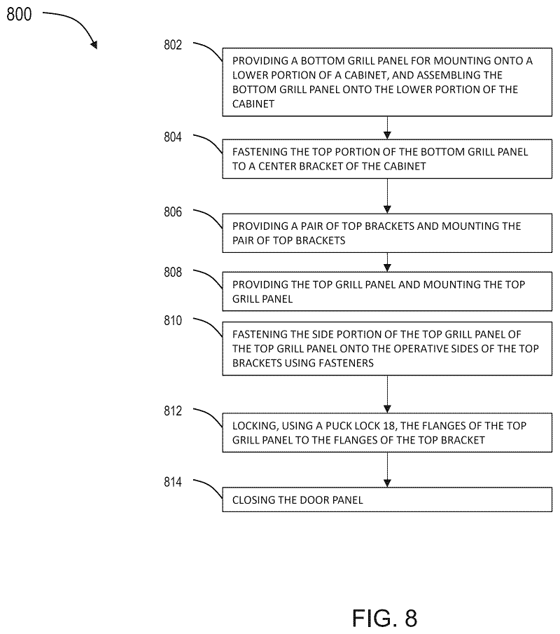

FIG. 8 illustrates a process flow diagram depicting a method 800 mounting the grill panel 10 on the operative portion of the cabinet 100, in accordance with one or more embodiments of the present disclosure. It is noted herein that the steps of method 800 may be implemented all or in part by grill panel 10 and/or any components, features, or the like shown in FIGS. 1 through 7B. It is further noted, however, that method 800 is not limited to grill panel 10 and/or any components, features, or the like shown in FIGS. 1 through 7B in that additional or alternative system-level embodiments may carry out all or part of the steps of method 800.

A step 802 includes providing a bottom grill panel 14 for mounting onto a lower portion of a cabinet 100, and assembling the bottom grill panel 14 onto the lower portion of the cabinet 100.

A step 804 includes fastening the top portion of the bottom grill panel 14 to the center bracket 22 of the cabinet 100.

A step 806 includes providing a pair of top brackets 20 and mounting the pair of the top brackets 20 onto an operative edge, defined along a vertical frame/column, of the cabinet 100 and mounting the top bracket 20 onto the inner surface of the cabinet 100 while ensuring that the flange extends towards the front of the cabinet 100.

A step 808 includes providing the top grill panel 12 and mounting the top grill panel 12, including engaging the lower portion of the top grill panel 12 onto the (slots) of the top portion of the bottom grill panel 14 and revolving the top grill panel 12 by aligning the flange 12a of the top grill panel 12 with the flange 20a of the top brackets 20.

A step 810 includes fastening the side portion of the top grill panel 12 of the top grill panel 12 onto the operative sides of the top brackets 20 using fasteners 24.

A step 812 includes locking, using a puck lock 18, the flanges 12a of the top grill panel 12 to the flanges 20a of the top bracket 20. This may ensure stability and security.

A step 814 includes closing the door panel 16. This may securely enclose the electronic components stored within the cabinet 100, completing the mounting process.

The foregoing description of the embodiments has been provided for purposes of illustration and not intended to limit the scope of the present disclosure.

Individual components of a particular embodiment are generally not limited to that particular embodiment, but, are interchangeable. Such variations are not to be regarded as a departure from the present disclosure, and all such modifications are considered to be within the scope of the present disclosure.

Embodiments are provided so as to thoroughly and fully convey the scope of the present disclosure to a person skilled in the art. Numerous details are set forth, relating to specific components, and methods, to provide a complete understanding of embodiments of the present disclosure. It will be apparent to the person skilled in the art that the details provided in the embodiments should not be construed to limit the scope of the present disclosure. In some embodiments, well-known processes, well-known apparatus structures, and well-known techniques are not described in detail.

The terminology used, in the present disclosure, is only for the purpose of explaining a particular embodiment and such terminology shall not be considered to limit the scope of the present disclosure. As used in the present disclosure, the forms “a,” “an,” and “the” may be intended to include the plural forms as well, unless the context clearly suggests otherwise. The terms “comprises,” “comprising,” “including,” and “having,” are open ended transitional phrases and therefore specify the presence of stated features, elements, modules, units, and/or components, but do not forbid the presence or addition of one or more other features, elements, components, and/or groups thereof.

The embodiments herein and the various features and advantageous details thereof are explained with reference to the non-limiting embodiments in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The foregoing description of the specific embodiments so fully reveals the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

Throughout this specification the word “comprises”, or variations such as “comprises” or “comprising”, will be understood to imply the inclusion of a stated element, or group of elements, but not the exclusion of any other element, or group of elements.

While considerable emphasis has been placed herein on the components and component parts of the preferred embodiments, it will be appreciated that many embodiments can be made and that many changes can be made in the preferred embodiments without departing from the principles of the disclosure. These and other changes in the preferred embodiment as well as other embodiments of the disclosure will be apparent to those skilled in the art from the disclosure herein, whereby it is to be distinctly understood that the foregoing descriptive matter is to be interpreted merely as illustrative of the disclosure and not as a limitation.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable” to each other to achieve the desired functionality. Specific examples of operably couplable include but are not limited to physically mateable and/or physically interacting components and/or wirelessly interactable and/or wirelessly interacting components and/or logically interacting and/or logically interactable components.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

We claim:

1. A grill panel configured to be mounted on an operative front portion of a cabinet, wherein the grill panel comprises:
a bottom grill panel configured to be mounted on a lower portion of the cabinet; and
a top grill panel configured to interlock with the bottom grill panel and configured to be mounted over the bottom grill panel, wherein an operative portion of the top grill panel is configured to interlock with an operative portion of the bottom grill panel.

2. The grill panel of claim 1,
wherein the grill panel comprises at least a pair of top brackets, each top bracket comprising a flange,
wherein the top grill panel comprises at least a pair of flanges, and wherein each flange of the top grill panel is configured to abut a corresponding flange of the at least the pair of the top brackets when the top grill panel is mounted over the bottom grill panel.

3. The grill panel of claim 2, wherein the corresponding flange of the top bracket comprises a hole and the flange of the top grill panel comprises a cavity, wherein the hole of the corresponding flange of the top bracket aligns with the cavity of the top grill panel when the flange of the top grill panel abuts the corresponding flange of the top bracket.

4. The grill panel of claim 2, wherein the corresponding flange of each top bracket and the flange of the top grill panel are configured to receive a puck lock configured to enclose and lock the corresponding flange of the top bracket and the flange of the top grill panel together.

5. The grill panel of claim 4, wherein the puck lock comprises a smart puck lock configured to be connected to a cloud server and remotely actuated.

6. The grill panel of claim 1, wherein the grill panel comprises an adapter plate configured to be mounted to an inner operative bottom surface of the cabinet, wherein the adapter plate is configured to form a predefined gap between an operative edge of the adapter plate and the operative portion of the cabinet, and wherein a lower operative portion of the bottom grill panel is configured to be received within the predefined gap.

7. The grill panel of claim 1, wherein the grill panel comprises a center bracket configured to be mounted to the operative front portion of the cabinet.

8. The grill panel of claim 7, wherein the center bracket is configured to partition the cabinet into an upper half cabinet and a lower half cabinet, and wherein an upper operative portion of the bottom grill panel is configured to be received and fastened to the center bracket.

9. The grill panel of claim 1, wherein the grill panel comprises at least two side plates and at least one base plate configured to be mounted in an inner operative portion of an upper half of the cabinet, wherein the at least two side plates and the at least one base plate are configured as a protective barrier for components from external tampering.

10. The grill panel of claim 1, wherein the bottom grill panel and the top grill panel are defined by a cage structure and include a webbed portion comprising an interconnected pattern of elements.

11. A cabinet comprising:
a grill panel mounted on an operative front portion of the cabinet;
a door panel configured to enclose the grill panel; and
a plurality of racks, each rack equipped with a battery restraining bracket,
wherein the grill panel comprises:
a bottom grill panel configured to be mounted on a lower portion of the cabinet; and
a top grill panel configured to interlock with the bottom grill panel and configured to be mounted over the bottom grill panel, wherein an operative portion of the top grill panel is configured to interlock with an operative portion of the bottom grill panel.

12. The cabinet of claim 11, wherein the grill panel further comprises at least a pair of top brackets, each top bracket comprising a flange, wherein the top grill panel comprises at least a pair of flanges, and wherein each flange of the top grill panel is configured to abut a corresponding flange of the at least the pair of the top brackets when the top grill panel is mounted over the bottom grill panel.

13. The cabinet of claim 12, wherein the top brackets are mounted in proximity to a side edge of the cabinet, wherein the top brackets are concealed when the top grill panel is mounted.

14. The cabinet of claim 11, wherein the interlocking of the operative portion of the top grill panel with the operative portion of the bottom grill panel forms an interlocking zone that restricts unauthorized opening or tampering with the top grill panel and the bottom grill panel.

15. The cabinet of claim 14, wherein the grill panel further comprises an adapter plate mounted to an inner operative bottom surface of the cabinet, wherein the adapter plate forms a predefined gap between an operative edge of the adapter plate and an operative portion of the cabinet, and wherein a lower operative portion of the bottom grill panel is received within the predefined gap.

16. The cabinet of claim 11, wherein the grill panel further comprises a center bracket mounted to the operative front portion of the cabinet, wherein the center bracket partitions the cabinet into an upper half cabinet and a lower half cabinet.

17. The cabinet of claim 16, wherein an upper operative portion of the bottom grill panel is received and fastened to the center bracket inside the cabinet by fasteners.

18. The cabinet of claim 11, wherein the grill panel further comprises at least two side plates and at least one base plate mounted in an inner operative portion of an upper half of the cabinet, wherein the side plates and the base plate provide a protective barrier.

19. The cabinet of claim 12, wherein the corresponding flange of the top bracket comprises a hole and the flange of the top grill panel comprises a cavity, wherein the hole of the corresponding flange of the top bracket aligns with the cavity of the top grill panel when the flange of the top grill panel abuts the corresponding flange of the top bracket.

20. A method of mounting a grill panel on an operative portion of a cabinet, the method comprising:
providing a bottom grill panel for mounting onto a lower portion of the cabinet, and assembling the bottom grill panel onto the lower portion of the cabinet;
fastening a top portion of the bottom grill panel to a center bracket of the cabinet;
providing a pair of top brackets and mounting the pair of the top brackets onto an operative edge defined along a vertical column of the cabinet;
providing a top grill panel and mounting the top grill panel;
fastening a side portion of the top grill panel of the top grill panel onto operative sides of the top brackets using fasteners;
locking, using a puck lock, flanges of the top grill panel to flanges of the top bracket; and
closing a door panel.
